(19) United States
(12) Patent Application Publication
(10) Pub. No.: US 2025/0043056 A1
(43) Pub. Date: Feb. 6, 2025

(54) PHOTOCURABLE RESINS WITH HIGH HEAT DEFLECTION TEMPERATURES

(71) Applicant: BASF SE, Ludwigshafen am Rhein (DE)

(72) Inventors: Lu ZHANG, Tarrytown, NY (US); John STEWART, Florham Park, NJ (US)

(21) Appl. No.: 18/716,539

(22) PCT Filed: Dec. 7, 2022
(86) PCT No.: PCT/US2022/052149

§ 371 Date: Jun. 5, 2024

Related U.S. Application Data
(60) Provisional application No. 63/287,302, filed on Dec. 8, 2021.

(51) Int. Cl. C08F 265/06; B29C 64/129; B29K 433/00; B33Y 10/00; B33Y 70/00

(52) U.S. Cl. CPC C08F 265/06; B29C 64/129; B33Y 10/00; B33Y 70/00; B29K 2433/00; B29K 2995/0017; B29K 2995/0077

(57) ABSTRACT

Described herein are photopolymerizable compositions for use in 3D printing. The compositions contain highly crosslinkable acrylate monomers, oligomers comprising a polyether acrylate oligomer, a polyester oligomer, an unsaturated polyester oligomer, or a combination thereof and a photoinitiator. The compositions, after photopolymerization, have a high heat deflection temperature, while maintaining strong mechanical properties. Also described are methods for fabricating three dimensional objects utilizing these compositions, and three dimensional objects made from these compositions.

### TECHNICAL FIELD

The present disclosure relates to 3D printing, or additive manufacturing, technologies, and, more specifically, it is related to additive manufacturing technologies based on photopolymerization of photocurable and 3D printable compositions for, stereolithography (SLA), Digital Light Processing (DLP), Continuous Liquid Interface Production (CLIP) and inkjet, and methods of use and preparation thereof.

### BACKGROUND OF THE INVENTION

In the discussion of the background that follows, reference is made to certain structures and/or methods. However, the following references should not be construed as an admission that these structures and/or methods constitute prior art. Applicant expressly reserves the right to demonstrate that such structures and/or methods do not qualify as prior art.

Photocurable compositions used in additive manufacturing technologies typically contain photoinitiators, monomers, oligomers, and additives. Upon exposure to light source(s) of certain wavelengths, radical polymerization is initiated to cure a network of monomers and oligomers.

In the past decades, additive manufacturing technologies, such as stereolithographic (SLA) and Digital Light Processing (DLP), were primarily centered on prototyping and were with limited manufacturing opportunities. Recently, the additive manufacturing industry is moving from prototyping to manufacturing, where one critical aspect is to develop advanced materials with properties that could match or surpass materials used in traditional manufacturing technologies such as injection molding.

Heat deflection temperature is a measure of resistance to distortion under a given load (for example, 0.455 MPa or 1.8 MPa) at elevated temperature. The test reports the temperature at which a given test bar will be deflected of 0.25 mm under a given load. This property is critical for 3D printed parts that require high temperature resistance, for example in electronics devices or automotive applications.

In this invention, we report the discovery that with the use of particular highly crosslinkable acrylate monomers, with three functional groups or more capable of crosslinking, in particular four functional groups or more, in combination with a polyether acrylate oligomer, polyester oligomer, unsaturated polyester oligomer, or combination thereof, it was possible to create formulations that provided 3D printed parts that exhibited high HDT, while maintaining physical characteristics, such as strength, that rendered the compositions useful in high temperature applications. This effect was further found where any of the above oligomers were used in combination with a urethane acrylate oligomer.

### BRIEF SUMMARY OF THE INVENTION

One aspect of the present technology relates to a composition which includes one or more highly crosslinkable monomers with at least three functional groups, for example at least four functional groups; and at least one elastic oligomer, wherein the composition is a UV curable composition. The oligomers may, for example, be a polyether acrylate oligomer, polyester oligomer, unsaturated polyester oligomer, or combinations thereof.

In another aspect of the present technology, the composition has a heat deflection temperature of at least 80° C., for example at least 100° C., in particular at least 150° C.

In another aspect of the present technology the UV curable composition contains ethoxylated pentaerythritol tetracrylate (PPTTA) as a highly crosslinkable monomer and an oligomer comprising polyether acrylate oligomer, polyester oligomer, unsaturated polyester oligomer, or combinations thereof. In one aspect, the above polyether acrylate oligomer, polyester oligomer, or unsaturated polyester oligomer may be employed in combination with a urethane acrylate oligomer.

In any embodiments, the compositions may be useful for CLIP, inkjet, SLA, and/or DLP 3D printing. In any embodiments, the composition may include one or more photoinitiators. The present technology also provides a package that includes any of the compositions described herein.

In another aspect, the present technology relates to a method for preparing a 3D article using the compositions described in any embodiment herein, the method includes applying successive layers of one or more of the compositions described herein in any embodiment to fabricate a 3D article; and irradiating the successive layers with UV irradiation. In any embodiments, the composition may be inkjet, CLIP, SLA, and/or DLP 3D printed. These successive layers may have a thickness from 50 to 200 μm. Thicker layers may allow for faster printing, while thinner layers may result in better resolution.

In yet another related aspect, the present technology provides a 3D article that includes UV cured successive layers of any of the compositions described herein. In any embodiments, the compositions may be deposited by inkjet, CLIP, SLA, or DLP.

### BRIEF DESCRIPTION OF THE DRAWINGS

FIG. 1A shows HDT versus various oligomers, as described in Example 3.

FIG. 1B shows tensile strength versus various oligomers, as described in Example 3.

FIG. 1C shows E-modulus versus various oligomers, as described in Example 3.

FIG. 1D shows percentage elongation at break versus various oligomers, as described in Example 3.

FIG. 2 shows HDT versus amount of L13, as described in Example 2b.

FIG. 3 shows HDT versus amount of L14, as described in Example 2c.

FIG. 4 shows HDT versus amount of L16, as described in Example 2d.

FIG. 5 shows HDT versus amount of L18, as described in Example 2e.

FIG. 6 shows HDT versus amount of L21, as described in Example 2f.

FIG. 7 shows HDT versus amount of L22, as described in Example 2g.

FIG. 8 shows HDT versus amount of oligomer, as described in Example 3.

FIG. 9A shows prediction profiler results of some of the formulations described in Example 4.

FIG. 9B shows prediction profiler results of some of the formulations described in Example 4.

FIG. 9C shows prediction profiler results of some of the formulations described in Example 4.

FIG. 9D shows prediction profiler results of some of the formulations described in Example 4.

### Definitions

Prior to describing the invention in further detail, the terms used in this application are defined as follows unless otherwise indicated.

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

“Optional” or “optionally” means that the subsequently described circumstance may or may not occur, so that the description includes instances where the circumstance occurs and instances where it does not.

The term “pre-determined” refers to an element whose identity is known prior to its use.

As used herein, the term “Stereolithography” or “SLA” refers to a form of 3D printing technology used for creating models, prototypes, patterns, and production of parts in a layer-by-layer fashion using photopolymerization, a process by which light causes chains of molecules to link, forming polymers. Those polymers then make up the body of a three-dimensional solid.

As used herein, the term “Digital Light Processing” or “DLP” refers to an additive manufacturing process, also known as 3D printing and similar to stereolithography, which takes a design created in a 3D modeling software and uses DLP technology to print a 3D object. DLP is a display device based on optical micro-electro-mechanical technology that uses a digital micromirror device. DLP may use as a light source in printers to cure resins into solid 3D objects.

As used herein, the term “Heat Deflection Temperature” or “HDT” is a measure of a polymer's resistance to distortion under a given load at elevated temperature. In other words, it is the temperature at which a given polymer test bar will be deflected by 0.25 mm under a given load. This heat deflection temperature may also be known as “deflection temperature under load,” or “heat distortion temperature.” It is tested in accordance with ASTM D 648.

### DETAILED DESCRIPTION OF THE INVENTION

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Disclosed is a composition for use in three-dimensional printing by way of photopolymerization.

In one embodiment, the highly crosslinkable monomer is an acrylate monomer according to Formula I:

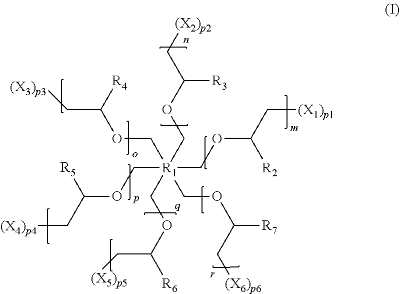

wherein R₁ is a branched or linear hydrocarbon chain with carbon, ether, ester or urethane linkages; R₂, R₃, R₄, R₅, R₆ and R₇ is independently —H or —CH₃; each of X₁, X₂, X₃, X₄, X₅ and X₆ is independently an acrylate moiety; each m, n, o, p, q and r is independently 0, 1, 2, 3, 4 or 5; wherein the sum of m, n, o, p, q and r is a value of from 0 to 6, preferably from 3 to 5, and each of p₁, p₂, p₃, p₄, p₅, and p₆ is independently 0 or 1; wherein the sum of p₁ through p₆ is a value of from 3 to 6, for example 3 or 4, 4 to 6, or 4 or 5.

In the photopolymerizable 3D printing compositions disclosed herein, the highly crosslinkable monomer is used in combination with a polyether acrylate oligomer, polyester oligomer, unsaturated polyester oligomer, or combinations thereof. These oligomers may be combined with one or more urethane acrylate oligomers.

Suitable polyether acrylates may be made, for example, from 50 to 75% by weight of a polyetherpolyol, from 20 to 50% by weight by weight of acrylic acid, and 5% by weight of customary auxiliaries. The terms “unsaturated polyester resin”, “vinyl ethers”, and “a-olefinically unsaturated polycarboxylic acids or their monoesters or diesters” are understood below always to include mixtures of different unsaturated polyester resins, mixtures of different vinyl ethers, and mixtures of different a-olefinically unsaturated polycarboxylic acids or their monoesters or diesters, respectively.

Unsaturated polyester resins a) are polyesters of polycarboxylic acids, preferably dicarboxylic acids, and polyols, preferably diols, the accompanying use of at least one a-olefinically unsaturated polycarboxylic acid as synthesis component being mandatory. a-Olefinically unsaturated polycarboxylic acids contemplated include more particularly maleic acid, fumaric acid, itaconic acid, mesaconic acid, citraconic acid; in the esterification, where possible, the compounds may also be used as the anhydride. Particularly preferred is maleic acid, which more particularly is also used as maleic anhydride.

Besides an a-olefinically unsaturated polycarboxylic acid, the unsaturated polyester resins may comprise further polycarboxylic acids and/or derivatives thereof such as anhydrides or esters with low molecular mass monoalcohols as a synthesis component. Examples include ortho-phthalic acid, isophthalic acid, terephthalic acid, trimellitic acid, trimesic acid, pyromellitic acid, tetrahydrophthalic acid, hexahydrophthalic acid, methylhexahydrophthalic acid, endomethylene-hexahydrophthalic acid, dicyclopentanedicarboxylic acid, succinic acid, glutaric acid, adipic acid, pimelic acid, suberic acid, azelaic acid, dodecanedicarboxylic acid, dimer fatty acids, resin acid adducts with acrylic acid or maleic acid, and also mixtures of such polycarboxylic acids.

Reaction partners of the polycarboxylic acids are polyols, preferably diols, such as, for example, ethylene glycol, propylene glycol, propane-1,3-diol; 2-methylpropane-1,3-diol; butane-1,4-diol; neopentyl glycol; ethylbutylpropanediol, and other so-called neo-diols (dialkylpropane-1,3-diols, alkylphenylpropane-1,3-diols); hydroxypivalic acid neopentyl glycol ester (HPN), pentane-1,5-diol; 2,2,4-trimethylpentane-1,3-diol; hexane-1,6-diol, trimethylhexanediol, dimer diols, dimethylolcyclohexane, dimethyloltricyclodecane, perhydrobisphenol A, ethoxylated bisphenol A. It is also possible, however, to use more highly polyfunctional polyols, such as glycerol, trimethylolethane, trimethylolpropane, ditrimethylolpropane, pentaerythritol, dipentaerythritol, trishydroxyethyl isocyanurate.

Unsaturated polyesters may also comprise monocarboxylic acids as synthesis components; these components are then located at the chain end, since only one esterification is possible. Mention may be made more particularly of 2-ethylhexanoic acid, isononanoic acid, isodecanoic acid, and other monocarboxylic acids prepared synthetically by the Koch or oxo process, pelargonic acid, distillation cuts of coconut fatty acids, palm kernel fatty acids and tallow, or else unsaturated fatty acids. The monocarboxylic acids are customarily used in conjunction with higher polyfunctional polyols. Mixtures may be used as well. One particular embodiment is the use of glycidyl esters of saturated monocarboxylic acids, in which case, as a result of the glycidyl ester group, further reactions and the attachment of further compounds are subsequently possible. Unsaturated polyester resins may also comprise hydroxycarboxylic acids and/or derivatives thereof, such as hydroxypivalic acid, dimethylolpropanoic acid, delta-valerolactone, epsilon-caprolactone, hydroxystearic acid.

The unsaturated polyesters preferably have an acid number of 0 to 40, preferably of 10 to 35 mg KOH/g; the number-average molecular weight is preferably 450 to 8000, more preferably 800 to 3000 g/mol. The equivalent mass, based on the molar fraction of the a-olefinic double bond, is preferably 170 to 1100, more preferably 200 to 800 g/mol; on the basis of the amount of a-olefinic double bonds, the equivalent mass gives the amount by weight of a-olefinically unsaturated polycarboxylic acids present in the polyester per mole of unsaturated polyesters.

The unsaturated polyesters can be prepared by customary processes described in the literature.

In another aspect of the present technology, in addition to the above mentioned highly crosslinkable monomers and elastic oligomers, the composition may have one or more dyes, pigments, or coloring agents. For example, such dyes, pigments, or coloring agents may be used to provide color or to avoid potential discoloration during printing and/or aging of the printed parts. Exemplary dyes, pigments, or coloring agents include carbon black pigment, white pigment and a variety of dyes like cyan, magenta, yellow etc. In particular the composition includes carbon black, for example in an amount of from 0.005 to 0.1% by weight, for example 0.01 to 0.1% by weight, in particular 0.01 to 0.05% by weight, based on the total weight of the composition. In formulations containing pigments, use may be made of one or more dispersants. Such dispersants would be known to an ordinary skilled artisan. For example, it may be possible to use EFKA4701. Dispersants may be used in an amount of around 10 to 100 ppm for example 20 to 50 ppm, in particular 20 ppm based on the weight of the total composition.

The compositions may include one or more photoinitiators. Suitable photoinitiators include, but are not limited to, bis(2,4,6-trimethylbenzoyl)-phenylphosphine oxide, 2,4,6-trimethylbenzoylphenyl phosphinate, bis(2,6-dimethoxybenzoyl)-2,4,4-trimethylpentylphosphine oxide, diphenyl(2,4,6-trimethylbenzoyl) phosphine oxide, alpha-hydroxy cyclohexyl phenyl ketone, 2-hydroxy-1-(4-(4-(2-hydroxy-2-methylpropionyl)benzyl)phenyl-2-methylpropan-1-one, 2-hydroxy-2-methyl-1-phenylpropanone, 2-hydroxy-2-methyl-1-(4-isopropylphenyl) propanone, oligo (2-hydroxy-2-m ethyl-1-(4-(1-methylvinyl)phenyl) propanone, 2-hydroxy-2-methyl-1-(4-dodecylphenyl) propanone, 2-hydroxy-2-methyl-1-[(2-hydroxyethoxy)phenyl]propanone, benzophenone, substituted benzophenones, and mixtures of any two or more thereof. In any embodiments, the one or more photoinitiators may be diphenyl(2,4,6-trimethylbenzoyl) phosphine oxide, ethyl(2,4,6-trimethylbenzoyl)phenylphosphinate, 1-hydroxycyclohexylphenylketone, and combinations of two or more thereof.

It has been unexpectedly found that a formulation comprising a highly crosslinkable monomer, such as pentaerythritol tetraacrylate, and an unsaturated polyester oligomer provides a composition that, following photopolymerization, displays a high HDT. These compositions may be used in three-dimensional printing to provide printed parts displaying a high HDT.

The HDT of the composition following photopolymerization may be about 80° C. or greater, about 100° C. or greater, about 150° C. or greater, or about 200° C. or greater.

The HDT of three-dimensional articles formed form the composition may be about 80° C. or higher, about 100° C. or greater, about 150° C. or greater, or about 200° C. or greater.

The weight ratio of the highly crosslinkable monomer to the unsaturated polyester oligomer may be about 0.3:0.7 or greater, about 0.4:0.6 or greater, about 0.5:0.5 or greater, about 0.6:0.4 or less, about 0.7:0.3 or less, or any value encompassed by these endpoints.

The weight percentage of ethoxylated pentaerythritol tetraacrylate may be from about 20 wt. % to about 60 wt. %, the weight percentage of the unsaturated polyester oligomer may be from about 25 wt. % to about 75 wt. %, and the weight percentage of the urethane acrylate oligomer may be from about 10 wt. % to about 50 wt. %, based on the total combined weight of the ethoxylated pentaerythritol tetraacrylate and the oligomers.

According to any embodiments, the composition may further include additional oligomers, which may further enhance the mechanical and chemical properties of the composition of the present technology. Suitable additional oligomers include, but are not limited to, urethane acrylates, epoxy, ethoxylated or propoxylated epoxy resins, polyesters, polyethers, polyketones, and mixtures of two or more thereof.

It has been surprisingly found that the addition of a urethane acrylate oligomer to a composition comprising a highly crosslinkable monomer, such as pentaerythritol tetraacrylate, and an unsaturated polyester oligomer may result in a composition that, following photopolymerization, displays high HDT.

In one embodiment, the urethane acrylate oligomer is a urethane(meth)acrylate of formula (III)

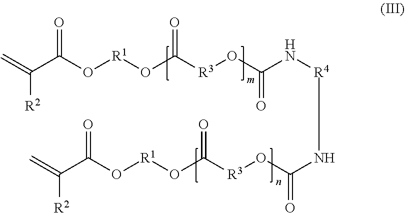

In the above formula, R₁ is a divalent alkylene radical which has 2 to 12 carbon atoms and which may optionally be substituted by C₁ to C₄ alkyl groups and/or interrupted by one or more oxygen atoms, said radical specifically having 2 to 10 carbon atoms, more specifically 2 to 8, and very specifically having 3 to 6 carbon atoms, R₂ in each case independently of any other is methyl or hydrogen, specifically hydrogen, R₃ is a divalent alkylene radical which has 1 to 12 carbon atoms and which may optionally be substituted by C₁ to C₄ alkyl groups and/or interrupted by one or more oxygen atoms, said radical having specifically 2 to 10, more specifically 3 to 8, and very specifically 3 to 4 carbon atoms, and n and m independently of one another are positive numbers from 1 to 5, specifically 2 to 5, more specifically 2 to 4, very specifically 2 to 3, and more particularly 2 to 2.5. R₄ here is a divalent organic radical which is formed by abstraction of both isocyanate groups from an aliphatic, cycloaliphatic or aromatic diisocyanate. Methods of making such urethane acrylate oligomers may be found, for example, in US 2016/0107987, the contents of which are incorporated herein by reference.

In an embodiment, the weight ratio of the ethoxylated pentaerythritol tetraacrylate to the unsaturated polyester oligomer may range from 0.2:0.8 to 0.8 to 0.2.

In an embodiment, the weight ratio of the ethoxylated pentaerythritol tetraacrylate to the unsaturated polyester oligomer to the urethane acrylate oligomer may range from 0.2:0.05:0.75 to 0.6:0.15:0.25, and preferably 0.4:0.1:0.5, or 0.3:0.3:0.4.

In any embodiments, the one or more photoinitiators may be present in an amount of about 0.01 wt. % to about 6.0 wt. % of the total weight of the composition. Suitable amounts of the photoinitiator include, but are not limited to, about 0.01 wt. % to about 6.0 wt. %, about 0.1 wt. % to about 4.0 wt. %, about 0.20 wt. % to about 3.0 wt. %, or about 0.5 wt. % to about 1.0 wt. %, or about 1 to 2 wt. %, based on the photopolymerizable composition. In one embodiment, the photoinitiator is present in an amount from 0.25 wt. % to about 2.0 wt. %. In another embodiment, the photoinitiator is present in an amount from 0.5 wt. % to about 1.0 wt. %.

According to any embodiments, solvents may be used to wash a 3D printed part after printing in order to remove uncured residual resin from the surface. Suitable solvents include, but are not limited to, propylene glycol monomethyl ether acetate, tripropylene glycol methyl ether, tripropylene glycol n-butyl ether, propylene glycol methyl ether, propylene glycol phenyl ether, propylene glycol n-butyl ether, propylene glycol diacetate, dipropylene glycol methyl ether, dipropylene glycol n-propyl ether, dipropylene glycol n-butyl ether, dipropylene glycol dimethyl ether, isopropanol and mixtures of two or more thereof and also their mixtures with water.

Applying the composition to obtain the three-dimensional article may include depositing the composition. In any embodiments, the application may include depositing a first layer of the composition and second layer of the composition to the first layer and successive layers thereafter to obtain a 3D article. Such depositing may include one or more methods, including but not limited to, UV inkjet printing, SLA, continuous liquid interface production (CLIP), and DLP. Other applications for the compositions include, but are not limited to, other coating and ink applications for printing, packaging, automotive, furniture, optical fiber, and electronics.

The methods described herein include contacting the layers of the composition with ultraviolet light irradiation to induce curing of the composition. In any embodiments, the contacting includes short wavelength and long wavelength ultraviolet light irradiation. Suitable short wavelength ultraviolet light irradiation includes UV-C or UV-B irradiation. In one embodiment, the short wavelength ultraviolet light irradiation is UV-C light. Suitable longwave ultraviolet light irradiation includes UV-A irradiation. Additionally, Electron Beam (EB) irradiation may be utilized to induce curing of the composition.

The methods described herein include repeating the deposition of layers of the composition and exposure to UV irradiation to obtain the 3D article. In any embodiments, the repeating may occur sequentially wherein depositing the layers of composition is repeated to obtain the 3D article prior to exposure to UV irradiation. In any embodiments, the repeating may occur subsequently wherein the deposing the layers of composition and exposure to UV irradiation are repeated after both steps.

In another related aspect, a 3D article is provided that includes UV cured successive layers of the any of the compositions as described herein. In any embodiments, the composition may have been inkjet, SLA, or DLP deposited.

In any embodiments, the 3D article may include a polishing pad or similar post processing technique. In any embodiments, polishing pad is a chemical mechanical polishing (CMP) pad. Polishing pads may be made following any known methods, for example the methods provided in U.S. Patent Appl. No. 2016/0107381, U.S. Patent Appl. No. 2016/0101500, and U.S. Pat. No. 10,029,405 (each incorporated herein by reference).

The present technology, thus generally described, will be understood more readily by reference to the following examples, which are provided by way of illustration and are not intended to be limiting of the present invention.

### EXAMPLES

All parts were printed with Origin printers (fixed wavelength: 385 nm) with an intensity of 8.5 mW/cm². Calibration across different Origin printers was conducted to ensure consistent laser intensity across different printers. Following printing, the printed parts were post-processed by first removing the parts from the build platform, then removing any residual photo-resin by washing the printed part in 99% isopropanol followed by a two-minute sonication in a 99% isopropanol bath at room temperature. The printed parts are then air dried and post-cured in a UV curing box (Creative CAD Works, Professional Curezone, with a 390-410 nm UV wavelength and an intensity of 25 mW/cm²) for two minutes on each side.

Tensile testing was conducted according to ASTM D638 with vertically 3-D printed tensile bars using an Instron 5965 Universal Testing System.

Heat deflection temperature (HDT) measurements were conducted according to ASTM D648 with vertically 3-D printed HDT bars using a Tinius Olsen HDT and VICAT Tester 3 Station, Model 303HDTM. All samples were measured at a load of 0.455 MPa.

Throughout the following examples, due care was taken to ensure that the testing was carried out using the same methods and materials. However, the printer utilized in carrying out the below testing results in variability outside of human control, and as a result there are differences in some of the data presented.

### Example 1: Raw Material Screening

In the following sections, the following abbreviations have these meanings: M1 is ethoxylated pentaerythritol tetraacrylate (PPTTA)., O1 is a urethane acrylate oligomer (UA 9089). A raw material screening study was conducted. To screen the raw materials, formulations were prepared with a weight ratio of M1:01: selected oligomer of 40:10:50. All formulations further contained 1 wt. % TPO photoinitiator. Specific descriptions are provided in Table 1 for each oligomer.

TABLE 1

| | | | | Tensile | |
|---|---|---|---|---|---|
| | | HDT, | | Strength, | |
| Oligomer | Composition | ° C. | STD | MPa | STD |
| L1 | Aromatic epoxy | 65.47 | 7.58 | 67.15 | 7.3 |
| | acrylate | | | | |
| L2 | Aromatic epoxy- | 54.13 | 1.91 | 59.43 | 6.97 |
| | modified acrylic | | | | |
| L3 | Polyether-modified | 78.77 | 1.88 | 36.31 | 6.8 |
| | acrylate | | | | |
| L4 | Urethane acrylate | 125.33 | 10.12 | 62.34 | 4.88 |
| L5 | Epoxy acrylate in | 58.27 | 1.53 | 77.12 | 2.23 |
| | diluent | | | | |
| L6 | Epoxy acrylate in | 60.57 | 1.29 | 78.03 | 2.09 |
| | diluent | | | | |
| L7 | Epoxy acrylate in | 56.27 | 2.65 | 74.6 | 4.4 |
| | diluent | | | | |
| L8 | Epoxy acrylate in | 58.6 | 1.28 | 72.46 | 7.33 |
| | diluent | | | | |
| L9 | Modified epoxy | 63.27 | 3.84 | 73.35 | 4.54 |
| | acrylate | | | | |
| L10 | Polyester acrylate | 42.00 | 0.10 | 54.84 | 1.02 |
| L11 | Polyester acrylate | 69.60 | 18.39 | 55.28 | 1.81 |
| L12 | Polyether acrylate | 77.30 | 2.46 | 50.91 | 7.31 |
| L13 | Polyether acrylate | 82.27 | 1.82 | 44.90 | 9.61 |
| L14 | Polyether acrylate | 91.87 | 2.98 | 61.12 | 3.26 |
| L15 | Polyester acrylate | 52.13 | 0.78 | 21.5 | 11.78 |
| L16 (Laromer | Polyester acrylate | 111.00 | 7.21 | 59.39 | 5.56 |
| PR 9052) | | | | | |
| L17 | Polyester acrylate | 55.83 | 0.76 | 67.03 | 7.21 |
| L18 (Laromer | Polyester acrylate | 128.00 | 10.58 | 65.83 | 11.91 |
| PR 9119) | | | | | |
| L19 | Urethane acrylates | 72.43 | 21.72 | 74.96 | 2.39 |
| L20 (Laromer | Urethane acrylates | 114.33 | 1.53 | 51.85 | 7.94 |
| UA 9048) | | | | | |
| L21 (Laromer | Unsaturated | 141.67 | 37.74 | 67.87 | 6.55 |
| UP 9118) | polyester acrylate | | | | |
| L22 (Laromer | Unsaturated | 93.77 | 28.28 | 77.31 | 7.49 |
| UP 9151) | polyester acrylate | | | | |

Additional results are shown in Table 2.

TABLE 2

| | | E- | | Elongation | |
|---|---|---|---|---|---|
| | | modulus, | | at | |
| Oligomer | Composition | MPa | STD | break, % | STD |
| L1 | Aromatic epoxy | 2294.27 | 52.37 | 4.09 | 0.6 |
| | acrylate | | | | |
| L2 | Aromatic epoxy- | 2101.85 | 46.35 | 3.93 | 0.69 |
| | modified acrylic | | | | |
| L3 | Polyether-modified | 2077.6 | 70.27 | 2.39 | 0.45 |
| | acrylate | | | | |
| L4 | Urethane Acrylate | 2482.17 | 63.42 | 3.17 | 0.26 |
| L5 | Epoxy acrylate in | 2559.15 | 43.56 | 4.19 | 0.26 |
| | diluent | | | | |
| L6 | Epoxy acrylate in | 2512.57 | 63.59 | 4.13 | 0.2 |
| | diluent | | | | |
| L7 | Epoxy acrylate in | 2542.39 | 126.01 | 4.04 | 0.47 |
| | diluent | | | | |
| L8 | Epoxy acrylate in | 2496.92 | 71.2 | 4 | 0.73 |
| | diluent | | | | |
| L9 | Modified epoxy | 2667.81 | 51.25 | 3.97 | 0.35 |
| | acrylate | | | | |
| L10 | Polyester acrylate | 1847.14 | 36.42 | 5.84 | 1.12 |
| L11 | Polyester acrylate | 1844.91 | 63.51 | 5.26 | 0.81 |
| L12 | Polyether acrylate | 1837.9 | 48.83 | 4.04 | 0.84 |
| L13 | Polyether acrylate | 2061.53 | 38.74 | 2.96 | 0.67 |
| L14 | Polyether acrylate | 2078.74 | 53.28 | 4.58 | 0.70 |
| L15 | Polyester acrylate | 2494.18 | 251.67 | 1.33 | 0.47 |
| L16 | Polyester acrylate | 2669.89 | 95 | 2.86 | 0.31 |
| L17 | Polyester acrylate | 2435.81 | 48.33 | 3.73 | 0.532 |
| L18 | Polyester acrylate | 2905.02 | 113.28 | 2.91 | 0.57 |
| L19 | Urethane acrylates | 2312.80 | 48.22 | 4.50 | 0.27 |
| L20 | Urethane acrylates | 2790.62 | 49.80 | 2.44 | 0.35 |
| L21 | Unsaturated | 2413.5 | 35.26 | 3.93 | 0.57 |
| | polyester acrylate | | | | |
| L22 | Unsaturated | 2642.56 | 74.48 | 4.1 | 0.53 |
| | polyester acrylate | | | | |

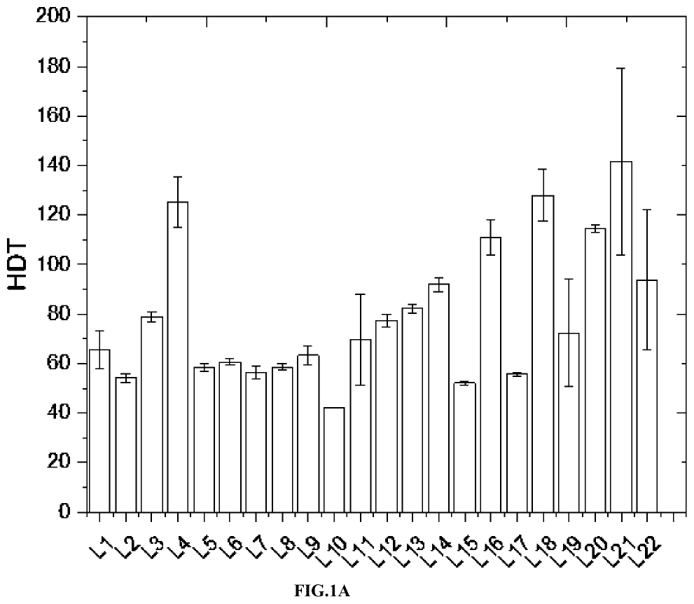

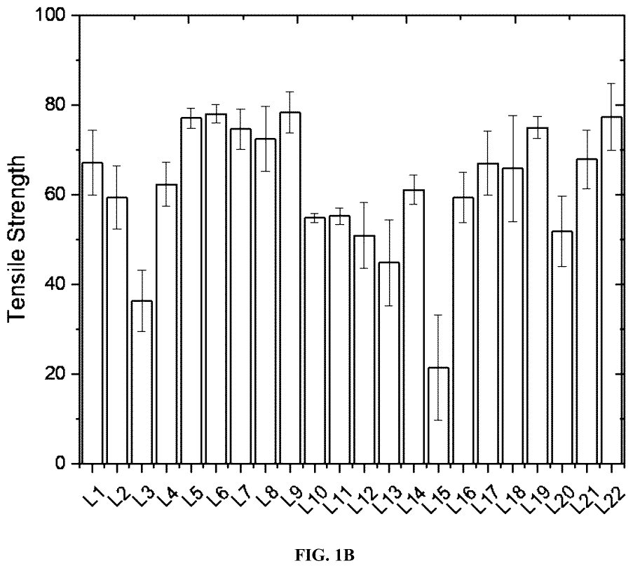

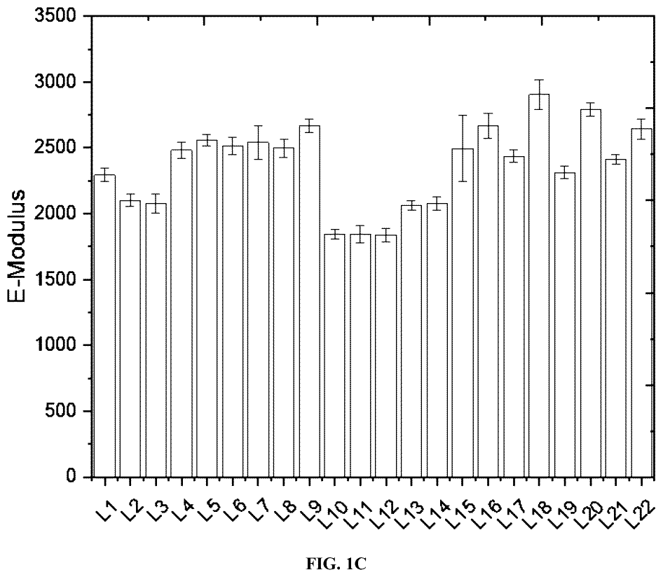

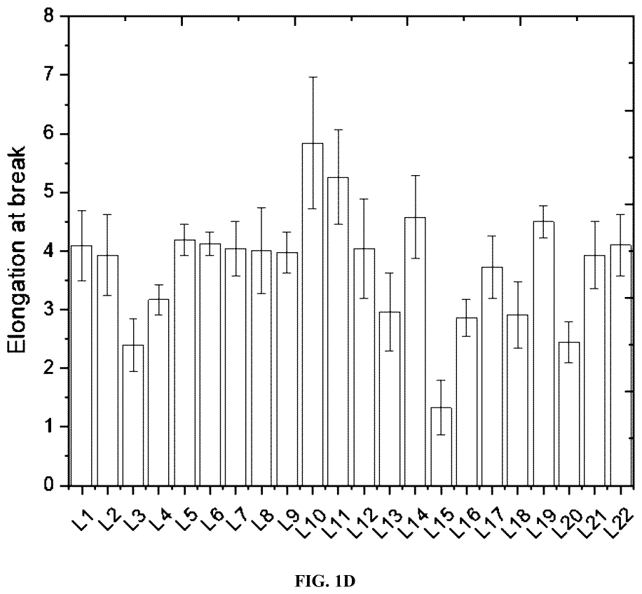

The results shown in Tables 1 and 2 are displayed graphically in FIGS. 1A, 1B, 1C, and 1D.

### Example 2a: Ladder Studies

From the results of the previous Examples, several raw materials were identified as candidates for further evaluation in ladder studies. Specifically, three formulations using varying amounts of M1 and a selected oligomer were prepared and tested. The general formulations are shown in the Table 3.

TABLE 3

| Formulation # | M1 | Selected Oligomer |
|---|---|---|
| 1 | 75 | 25 |
| 2 | 50 | 50 |
| 3 | 25 | 75 |

### Example 2b: Ladder Study with L13

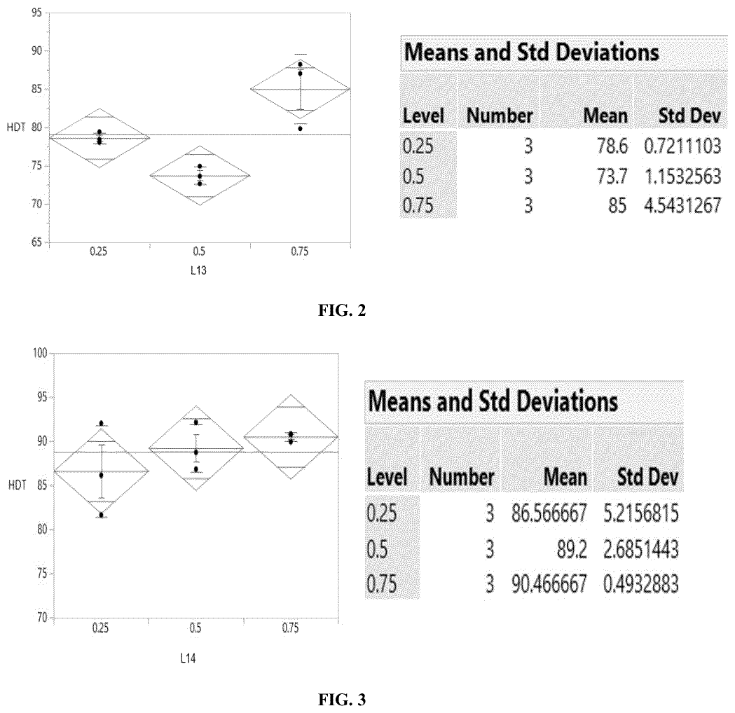

The results of the ladder study for formulations including L13 are shown in Table 4, where all L13 formulations exhibit a low tensile strength and elongation. Formulation 2 exhibits the lowest HDT among all three formulations, with an average HDT of 73.7° C. Formulation 3 exhibits the highest HDT among the three formulations, with an average HDT of 85° C., all of which are illustrated graphically in FIG. 2.

TABLE 4

| | | | | | | E- | | Tensile | |
|---|---|---|---|---|---|---|---|---|---|
| | | HDT, | | Elongation | | Modulus | | Strength | |
| L13 | M1 | ° C. | STD | % | STD | MPa | STD | MPa | STD |
| 25 | 75 | 78.6 | 0.72 | 1.59 | 0.19 | 2190.03 | 23.41 | 25.62 | 2.95 |
| 50 | 50 | 73.7 | 1.15 | 1.6 | 0.25 | 2181.11 | 61.32 | 26.75 | 3.39 |
| 75 | 25 | 85 | 4.54 | 1.18 | 0.18 | NA | NA | 16.48 | 1.49 |

### Example 2c: Ladder Study with L14

The results of the ladder study for formulations including L14 are shown in Table 5, where increasing the amount of L14 level from 25 wt. % to 75 wt. % leads to a small increase in average HDT (from 86.57° C. to 90.47° C.) and elongation (from 2.26% to 3.55%). The E-modulus of each of the three formulations is approximately 2000 MPa. The average tensile strength of formulation 1 is 35 MPa, increasing to 56 MPa for formulation 2 and formulation 3. The effect on HDT as a function of the amount of L14 is shown graphically in FIG. 3.

TABLE 5

| | | | | | | E- | | Tensile | |
|---|---|---|---|---|---|---|---|---|---|
| | | HDT, | | Elongation | | Modulus | | Strength | |
| L14 | M1 | ° C. | STD | % | STD | MPa | STD | MPa | STD |
| 25 | 75 | 86.57 | 5.22 | 2.26 | 0.63 | 2147.95 | 127.63 | 35.25 | 8.74 |
| 50 | 50 | 89.2 | 2.69 | 3.86 | 0.67 | 1985.67 | 43.22 | 56.12 | 4.94 |
| 75 | 25 | 90.47 | 0.49 | 3.55 | 0.36 | 2016.96 | 25.5 | 55.78 | 4.11 |

### Example 2d: Ladder Study with L16

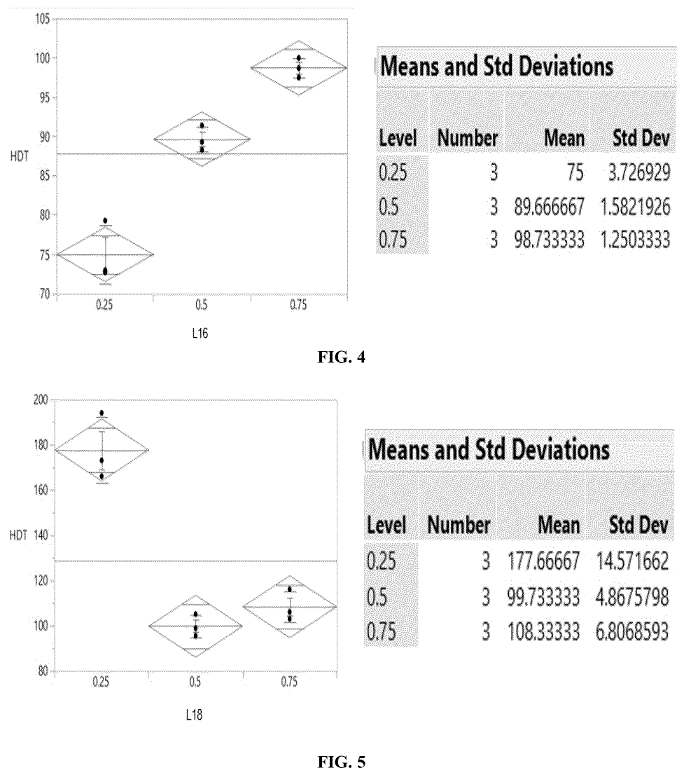

The results of the ladder study for formulations including L16 are shown in Table 6, where increasing the amount of L16 leads to moderate increase in elongation and E-modulus, and 38% improvement in tensile strength when comparing the formulation with 75 wt. % L16 to the formulation including 25 wt. % L16. A significant increase in HDT is observed upon increasing the amount of L16 from 25 wt. % to 75 wt. %, as shown in FIG. 4. Formulation 1 exhibits an average HDT of 75° C.; formulation 2 exhibits an average HDT of 90° C.; and formulation 3 exhibits an average HDT of 99° C.

TABLE 6

| | | | | | | E- | | Tensile | |
|---|---|---|---|---|---|---|---|---|---|
| | | HDT, | | Elongation | | Modulus | | Strength | |
| L16 | M1 | ° C. | STD | % | STD | MPa | STD | MPa | STD |
| 25 | 75 | 75 | 3.73 | 1.94 | 0.64 | 2460.71 | 120.08 | 36.04 | 11.02 |
| 50 | 50 | 89.67 | 1.58 | 2.57 | 0.69 | 2588.13 | 102.9 | 48.76 | 10.76 |
| 75 | 25 | 98.73 | 1.25 | 2.27 | 0.44 | 2693.48 | 135.43 | 49.9 | 8.59 |

### Example 2e: Ladder Study with L18

The results of the ladder study for formulations including L18 are shown in Table 7, where increasing the amount of L18 leads to a decrease in elongation and an increase in E-modulus. The impact on tensile strength is limited, and formulation 2 exhibits the highest average tensile strength (39.84 MPa). The amount of L18 leads to significant differences in HDT. Formulation 1 exhibits an average HDT of 177.67° C. with a standard deviation of 14.57° C. Formulation 2 and Formulation 3 exhibit much lower HDT at 99.73 and 108.33 respectively, as shown in FIG. 5.

TABLE 7

| | | | | | | E- | | Tensile | |
|---|---|---|---|---|---|---|---|---|---|
| | | HDT, | | Elongation | | Modulus | | Strength | |
| L18 | M1 | ° C. | STD | % | STD | MPa | STD | MPa | STD |
| 25 | 75 | 177.67 | 14.57 | 1.95 | 0.34 | 2710.99 | 82.12 | 37.81 | 8.07 |
| 50 | 50 | 99.73 | 4.87 | 1.86 | 0.48 | 3005.79 | 100.13 | 39.84 | 13.01 |
| 75 | 25 | 108.33 | 6.81 | 1.4 | 0.31 | 3192.51 | 162.87 | 32.01 | 7.1 |

### Example 2f: Ladder Study with L21

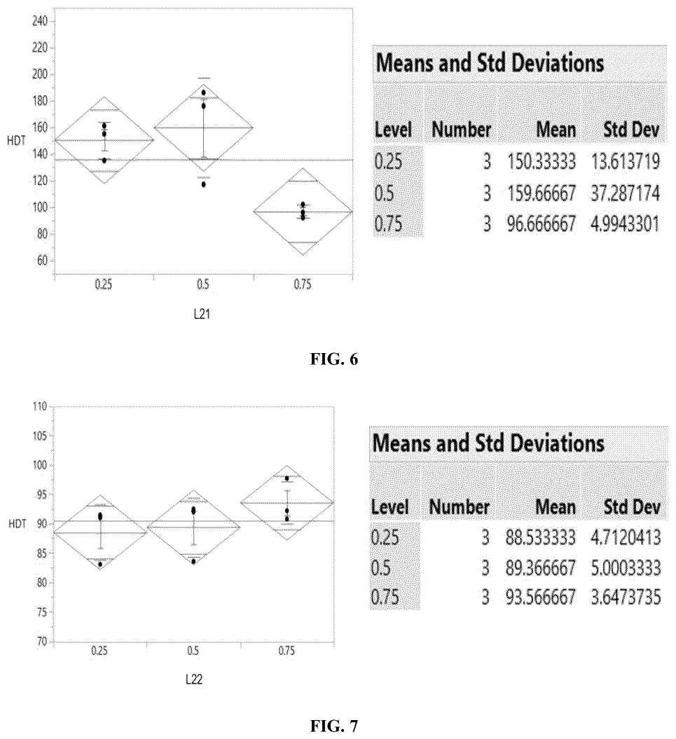

The results of the ladder study for formulations including L21 are shown in Table 8, where increasing the amount of L21 leads to a decrease in elongation and tensile strength. The impact on E-modulus is limited, with formulation 2 exhibiting the highest average E-modulus (2269.65 MPa). Formulation 1 exhibits an average HDT of 150° C.; formulation 2 exhibits an average HDT of 160° C. with a high standard deviation (37° C.) and formulation 3 exhibits an average HDT of 97° C., as shown in FIG. 6.

TABLE 8

| | | | | | | E- | | Tensile | |
|---|---|---|---|---|---|---|---|---|---|
| | | HDT, | | Elongation, | | Modulus, | | Strength, | |
| L21 | M1 | ° C. | STD | % | STD | MPa | STD | MPa | STD |
| 25 | 75 | 150.33 | 13.61 | 4.08 | 0.36 | 2225.71 | 68.88 | 69.23 | 3.85 |
| 50 | 50 | 159.67 | 37.29 | 3.37 | 0.72 | 2269.65 | 141.27 | 57.19 | 12.29 |
| 75 | 25 | 96.67 | 4.99 | 2.86 | 0.73 | 2130.92 | 113.3 | 47.18 | 10.85 |

### Example 2g: Ladder Study with L22

The results of the ladder study for formulations including L22 are shown in Table 9, where varying the level of L22 does not lead to significant changes in HDT (as shown in FIG. 7), elongation, E-modulus or tensile strength.

TABLE 9

| | | | | | | E- | | Tensile | |
|---|---|---|---|---|---|---|---|---|---|
| | | HDT, | | Elongation, | | Modulus | | Strength | |
| L22 | M1 | ° C. | STD | % | STD | MPa | STD | MPa | STD |
| 25 | 75 | 88.53 | 4.71 | 3.71 | 0.62 | 2348.41 | 62.88 | 68.23 | 5.68 |
| 50 | 50 | 89.37 | 5.00 | 4.22 | 0.35 | 2562.69 | 93.76 | 77.51 | 5.74 |
| 75 | 25 | 93.57 | 3.65 | 4.14 | 0.52 | 2292.29 | 87.32 | 70.4 | 5.17 |

### Example 3: Ladder Study with Three-Component Formulation

The formulations from the raw materials screening studies selected for further study included M1, 01, and L21. Therefore, an additional ladder study using these three components was conducted. The ratio of M1 to 01 was fixed at 4:1, and the amount of L21 was increased from 25 wt. % to 75 wt. %. The specific formulations are shown in Table 10.

TABLE 10

| Formulation # | M1 | O1 | L21 |
|---|---|---|---|
| 1 | 60 | 15 | 25 |
| 2 | 40 | 10 | 50 |
| 3 | 20 | 5 | 75 |

Ladder studies were conducted on the formulations, with the results shown in Table 11.

TABLE 11

| | | | | | E- | | Tensile | |
|---|---|---|---|---|---|---|---|---|
| Formulation | HDT, | | Elongation | | Modulus | | Strength | |
| # | ° C. | STD | % | STD | MPa | STD | MPa | STD |
| 1 | 132.17 | 36.35 | 3.95 | 0.44 | 2050.97 | 28.52 | 61.45 | 2.74 |
| 2 | 201.67 | 26.79 | 3.68 | 0.68 | 2249.3 | 68.05 | 65.13 | 9.73 |
| 3 | 140.17 | 5.19 | 4.51 | 0.16 | 2261.13 | 60.9 | 73.93 | 2.13 |

As shown above, the results of the ladder study for the formulation including M1, O1 and L21, increasing the amount of L21 leads to an increase in tensile strength. All three formulations exhibit relatively high HDT. Formulation 2 exhibited the best overall performance, with HDT of 201.67±26.79° C., elongation of 3.68±0.68%, E-modulus of 2249.3±68.05 MPa, and tensile strength of 65.13±9.73 MPa. Formulation 1 and formulation 3 exhibit an average HDT of 132° C. and 140° C. respectively.

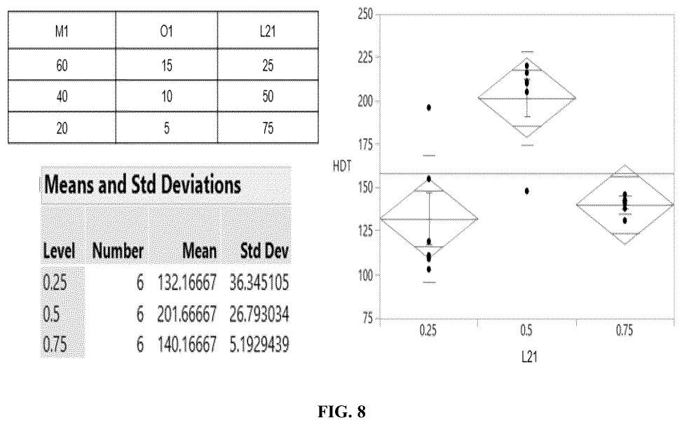

Formulation 2 exhibits the highest HDT among all formulations tested; however, this formulation exhibited a wide variance in HDT, possibly due to defects during printing. Formulation 3 also exhibits a relatively high HDT with an average of 140° C. In addition, the standard deviation of the HDT is much smaller at 5.19° C., indicating improved repeatability. The change in HDT as a function of the amount of oligomer is shown graphically in FIG. 8.

### Example 4: Formulation Optimization

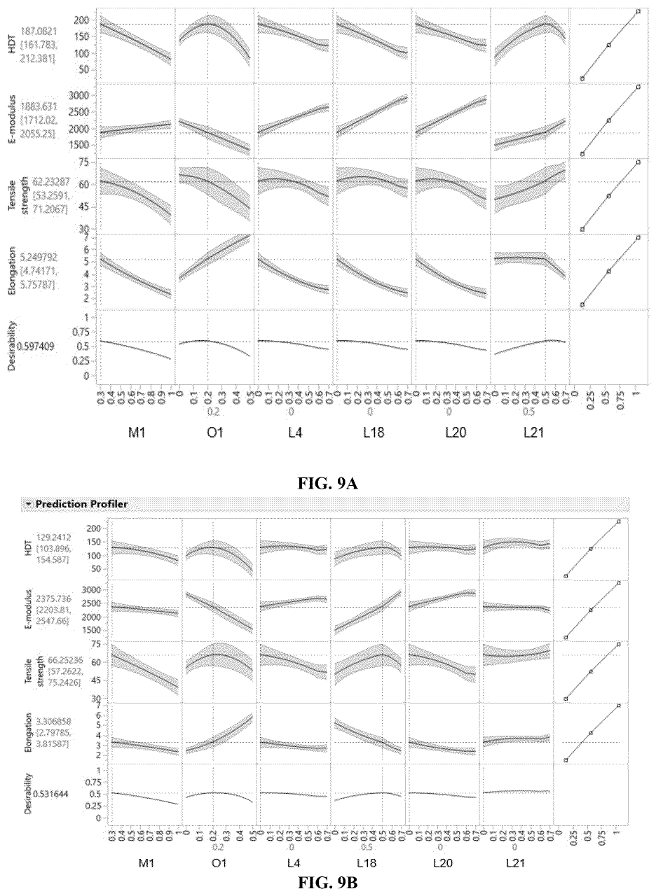

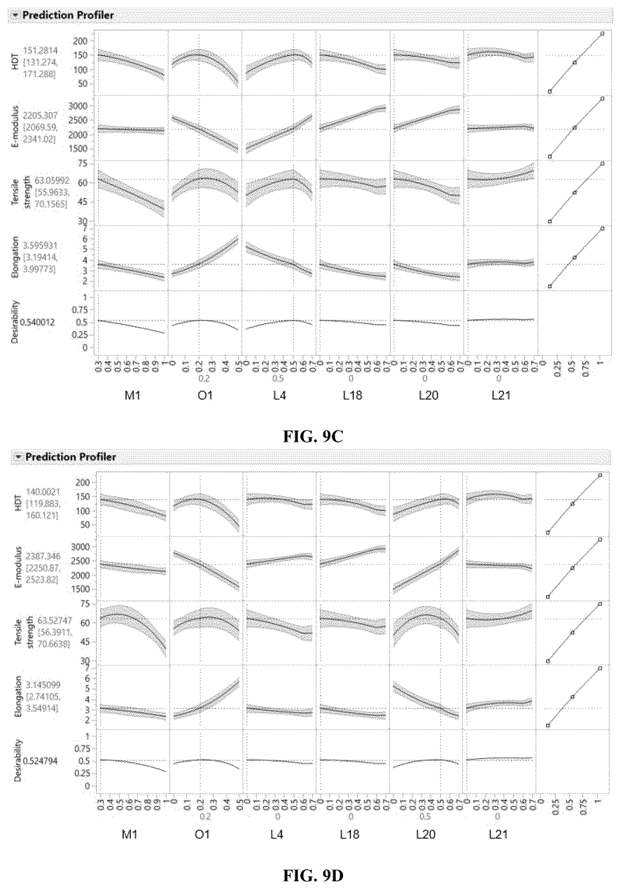

Based on the results and raw materials screening and ladder studies described above, M1, O1, LA, L18, L20 and L21 were selected for further evaluation. Among these formulations, 34 were identified as having an average HDT above 90° C. (all formulations excepting numbers 18, 21, 26, 27, 28, 32, 33 and 42). A further 26 formulations (with the exceptions of 7, 10, 18, 20, 21, 24, 25, 26, 27, 28, 30, 32, 33, 34, 41 and 42) were identified as having an average HDT greater than 100° C. Fifteen formulations (all formulations with the exceptions of numbers 1, 2, 4, 5, 7, 10, 13, 15, 18, 19, 20, 21, 22, 24, 25, 26, 27, 28, 29, 30, 32, 33, 34, 37, 39, 41 and 42) were identified as having with an average HDT above 120° C. Four formulations (numbers 6, 12, 17, and 23) were identified as having an average HDT of greater than 150° C. Finally, one formulation (number 6) exhibited an average HDT of 203° C. The prediction profiler results are shown graphically in FIGS. 9A, 9B, 9C, and 9D.

TABLE 12

| Sample # | M1 | O1 | L4 | L18 | L20 | L21 |
|---|---|---|---|---|---|---|
| 1 | 0.65 | 0 | 0 | 0 | 0.35 | 0 |
| 2 | 0.3 | 0 | 0.35 | 0.35 | 0 | 0 |
| 3 | 0.3 | 0 | 0.35 | 0 | 0 | 0.35 |
| 4 | 0.3 | 0 | 0 | 0.35 | 0.35 | 0 |
| 5 | 0.3 | 0 | 0.35 | 0 | 0 | 0.35 |
| 6 | 0.3 | 0.3 | 0 | 0 | 0 | 0.4 |
| 7 | 0.65 | 0 | 0 | 0.35 | 0 | 0 |
| 8 | 0.3 | 0 | 0.7 | 0 | 0 | 0 |
| 9 | 0.3 | 0 | 0 | 0 | 0.7 | 0 |
| 10 | 0.65 | 0 | 0 | 0 | 0 | 0.35 |
| 11 | 0.3 | 0 | 0 | 0 | 0.7 | 0 |
| 12 | 0.3 | 0 | 0 | 0 | 0.25 | 0.45 |
| 13 | 0.3 | 0 | 0 | 0.35 | 0 | 0.35 |
| 14 | 0.65 | 0 | 0.35 | 0 | 0 | 0 |
| 15 | 0.3 | 0 | 0.35 | 0 | 0.35 | 0 |
| 16 | 0.3 | 0 | 0 | 0.7 | 0 | 0 |
| 17 | 0.3 | 0.3 | 0.4 | 0 | 0 | 0 |
| 18 | 1 | 0 | 0 | 0 | 0 | 0 |
| 19 | 0.3 | 0 | 0 | 0.35 | 0 | 0.35 |
| 20 | 0.3 | 0 | 0.35 | 0.35 | 0 | 0 |
| 21 | 0.3 | 0.5 | 0.2 | 0 | 0 | 0 |
| 22 | 0.65 | 0 | 0 | 0 | 0 | 0.35 |
| 23 | 0.3 | 0 | 0 | 0 | 0 | 0.7 |
| 24 | 0.65 | 0 | 0 | 0.35 | 0 | 0 |
| 25 | 0.7 | 0.3 | 0 | 0 | 0 | 0 |
| 26 | 0.3 | 0.5 | 0 | 0 | 0 | 0.2 |
| 27 | 0.65 | 0 | 0 | 0 | 0.35 | 0 |
| 28 | 1 | 0 | 0 | 0 | 0 | 0 |
| 29 | 0.3 | 0.3 | 0 | 0.4 | 0 | 0 |
| 30 | 0.3 | 0 | 0 | 0.7 | 0 | 0 |
| 31 | 0.3 | 0 | 0.35 | 0 | 0.35 | 0 |
| 32 | 0.3 | 0.5 | 0 | 0 | 0.2 | 0 |
| 33 | 0.5 | 0.5 | 0 | 0 | 0 | 0 |
| 34 | 0.65 | 0 | 0.35 | 0 | 0 | 0 |
| 35 | 0.3 | 0 | 0 | 0 | 0.25 | 0.45 |
| 36 | 0.3 | 0 | 0 | 0 | 0 | 0.7 |
| 37 | 0.3 | 0.3 | 0.4 | 0 | 0 | 0 |
| 38 | 0.3 | 0 | 0.7 | 0 | 0 | 0 |
| 39 | 0.3 | 0.3 | 0 | 0 | 0.4 | 0 |
| 40 | 0.3 | 0.3 | 0 | 0 | 0.4 | 0 |
| 41 | 0.3 | 0 | 0 | 0.35 | 0.35 | 0 |
| 42 | 0.3 | 0.5 | 0 | 0.2 | 0 | 0 |

TABLE 13

| | | Elongation at | E-modulus, | Tensile strength, |
|---|---|---|---|---|
| Sample # | HDT, ° C. | Break, % | MPa | MPa |
| 1 | 100.117 | 2.15 | 2557.29 | 74.63 |
| 2 | 107 | 2.47 | 2828.79 | 58.93 |
| 3 | 132.667 | 3.63 | 2446.84 | 65.74 |
| 4 | 113.667 | 2.03 | 2996.31 | 46.63 |
| 5 | 115.333 | 3.38 | 2389.24 | 62.6 |
| 6 | 203 | 6.23 | 1751.91 | 56.55 |
| 7 | 93.7333 | 2.69 | 2623.23 | 48.7 |
| 8 | 124 | 2.21 | 2613.5 | 40.66 |
| 9 | 124.333 | 2.7 | 2793.01 | 47.12 |
| 10 | 92.7 | 3.57 | 2167.63 | 59.25 |
| 11 | 124.333 | 2.47 | 2743.26 | 57.2 |
| 12 | 162.667 | 3.48 | 2402.96 | 67.83 |
| 13 | 118.467 | 3.09 | 2580.55 | 67.66 |
| 14 | 139.667 | 2.91 | 2276.67 | 52.32 |
| 15 | 107.067 | 2 | 3131.01 | 44.42 |
| 16 | 126.667 | 2.73 | 2609.39 | 55.76 |
| 17 | 160 | 4.12 | 1991 | 64.06 |
| 18 | 79.7 | 2.05 | 2099.9 | 35.91 |
| 19 | 104.4 | 2.59 | 2604.04 | 53.51 |
| 20 | 98.9 | 2.37 | 2863.38 | 51.48 |
| 21 | 54.2 | 6.37 | 1444.12 | 50.68 |
| 22 | 104.533 | 3 | 2216.22 | 54.8 |
| 23 | 153.333 | 3.77 | 2199.51 | 65.38 |
| 24 | 90.6333 | 2.29 | 2642.2 | 50.58 |
| 25 | 99.4 | 4.13 | 1632.32 | 51.09 |
| 26 | 50.4667 | 6.84 | 1304.06 | 44.61 |
| 27 | 88.3667 | 2.48 | 2404.3 | 49.07 |
| 28 | 79.9333 | 2 | 2145.76 | 33.16 |
| 29 | 109.333 | 4.01 | 2086.08 | 65.94 |
| 30 | 98.7667 | 2.56 | 2957.44 | 62.44 |
| 31 | 124 | 2.39 | 2657.28 | 49.62 |
| 32 | 54.8 | 5.41 | 1627.97 | 54.48 |
| 33 | 59.3333 | 6.57 | 1380.49 | 45.97 |
| 34 | 99.0333 | 2.85 | 2310.38 | 50.65 |
| 35 | 147 | 3.02 | 2452.53 | 64.55 |
| 36 | 134.667 | 3.69 | 2272.85 | 66.19 |
| 37 | 118.667 | 4.11 | 2005.35 | 63.61 |
| 38 | 126.667 | 3.17 | 2583.44 | 56.97 |
| 39 | 119.333 | 3.98 | 2126.22 | 65.65 |
| 40 | 121.333 | 3.89 | 2093.69 | 62.15 |
| 41 | 97.5667 | 2.67 | 3013.89 | 55.14 |
| 42 | 54.8333 | 5.82 | 1565.12 | 52.63 |

### Example 5: Formulation Touting

According to DOB results, four formulations were added for testing, as shown in Table 14.

TABLE 14

| Sample # | M1 | O1 | L4 | L18 | L20 | L21 |
|---|---|---|---|---|---|---|
| 43 | 0.3 | 0.2 | 0 | 0 | 0 | 0.5 |
| 44 | 0.3 | 0.2 | 0 | 0.5 | 0 | 0 |
| 45 | 0.3 | 0.2 | 0.5 | 0 | 0 | 0 |
| 46 | 0.3 | 0.2 | 0 | 0 | 0.5 | 0 |

TABLE 15

| | | | | | E- | | Tensile | |
|---|---|---|---|---|---|---|---|---|
| Sample | HDT, | | Elongation | | Modulus | | Strength | |
| # | ° C. | STD | % | STD | MPa | STD | MPa | STD |
| 43 | 140 | 46.23 | 4.81 | 0.42 | 1868.91 | 51.2 | 59.78 | 1.54 |
| 44 | 98.67 | 4.163 | 3.18 | 0.45 | 2376.1 | 59.92 | 62.6 | 6.69 |
| 45 | 109.67 | 5.032 | 3.36 | 0.61 | 2213.3 | 42.47 | 58.65 | 7.39 |
| 46 | 142 | 27.22 | 2.96 | 0.54 | 2317.13 | 110.18 | 56.34 | 9.26 |

Preferred embodiments of this invention are described herein, including the best mode known to the inventors for carrying out the invention. It will be appreciated that the invention is not restricted to the details described above with reference to the preferred embodiments, but that numerous modifications and variations can be made without departing from the spirit and scope of the invention as defined by the following claims.

1.-23. (canceled)

24. A photopolymerizable composition comprising:
at least one highly crosslinkable acrylate monomer with a functionality of 3 or higher;
at least one of a polyether acrylate oligomer, a polyester oligomer, an unsaturated polyester oligomer, or a combination thereof; and
at least one photoinitiator.

25. The photopolymerizable composition according to claim 24, wherein the at least one highly crosslinkable acrylate monomer is an acrylate monomer according to Formula I: 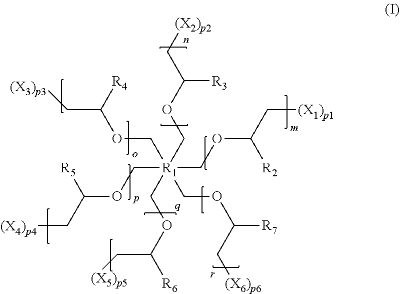
wherein
R₁ is a branched or linear hydrocarbon chain with carbon, ether, ester or urethane linkages; R₂, R₃, R₄, R₅, R₆ and R₇ is independently —H or —CH₃; each of X₁, X₂, X₃, X₄, X₅ and X₆ is independently an acrylate moiety; each m, n, o, p, q and r is independently 0, 1, 2, 3, 4 or 5; wherein the sum of m, n, o, p, q and r is a value of from 3 to 5, and each of p₁, p₂, p₃, p₄, p₅, and p₆ is independently 0 or 1; wherein the sum of p₁ through p₆ is a value of from 3 to 6

26. The photopolymerizable composition according to claim 25, wherein the sum of p₁, p₂, p₃, p₄, p₅, and p₆ is a value of from 4 to 5.

27. The photopolymerizable composition according to claim 24, wherein the highly crosslinkable acrylate monomer is ethoxylated pentaerythritol tetraacrylate.

28. The photopolymerizable composition according to claim 24, comprising:
ethoxylated pentaerythritol tetraacrylate; and
an unsaturated polyester oligomer.

29. The photopolymerizable composition according to claim 28, wherein the weight ratio of the ethoxylated pentaerythritol tetraacrylate and the unsaturated polyester oligomer is from 0.2:0.8 to 0.8 to 0.2.

30. The photopolymerizable composition according to claim 29, further comprising a urethane acrylate oligomer.

31. The photopolymerizable composition according to claim 24, wherein the weight percentage of ethoxylated pentaerythritol tetraacrylate is from about 20 wt. % to about 60 wt. %, the weight percentage of the unsaturated polyester oligomer is from about 25 wt. % to about 75 wt. %, and the weight percentage of the urethane acrylate oligomer is from about 10 wt. % to about 50 wt. %, based on the total combined weight of the ethoxylated pentaerythritol tetraacrylate and the oligomers.

32. The photopolymerizable composition according to claim 24, wherein the weight ratio of ethoxylated pentaerythritol tetraacrylate to unsaturated polyester oligomer to urethane acrylate oligomer is 0.2:0.05:0.75 to 0.6:0.15:0.25.

33. The photopolymerizable composition according to claim 24, wherein the weight ratio of ethoxylated pentaerythritol tetraacrylate to unsaturated polyester oligomer to urethane acrylate oligomer is 0.4:0.1:0.5.

34. The photopolymerizable composition according to claim 24, wherein the weight ratio of ethoxylated pentaerythritol tetraacrylate to unsaturated polyester oligomer to urethane acrylate oligomer is 0.3:0.3:0.4.

35. The photopolymerizable composition according to claim 24, wherein the composition, after photopolymerization, has a heat deflection temperature of at least 100° C.

36. The photopolymerizable composition according to claim 35, wherein the composition, after photopolymerization, has a heat deflection temperature of at least 150° C.

37. The photopolymerizable composition according to claim 36, wherein the composition, after photopolymerization, has a heat deflection temperature of at least 200° C.

38. A package comprising the composition of claim 24.

39. A method of preparing a three-dimensional article, wherein the method comprises applying successive layers of one or more of the compositions of claim 24 to fabricate a three-dimensional article, and irradiating the successive layers with UV irradiation.

40. The method of claim 39, wherein the applying comprises depositing a first layer of the composition to a substrate and applying a second layer of the composition to the first layer and optionally applying successive layers thereafter.

41. The method of claim 39, wherein the three-dimensional article has a heat deflection temperature of at least 100° C.

42. The method of claim 39, wherein the three-dimensional article has a heat deflection temperature of at least 150° C.

43. A three-dimensional article comprising UV cured successive layers of the composition of claim 24.

44. A three-dimensional article produced by the method of claim 39.

45. The three-dimensional article of claim 43, wherein the three dimensional article has a heat deflection temperature of at least 100° C.

46. The three-dimensional article of claim 43, wherein the three dimensional article has a heat deflection temperature of at least 150° C.
